(19) United States
(12) Patent Application Publication
(10) Pub. No.: US 2016/0111675 A1
(43) Pub. Date: Apr. 21, 2016

(54) ORGANIC LIGHT-EMITTING DEVICE

(71) Applicant: OLEDWorks GmbH, Aachen (DE)

(72) Inventors: Jens MEYER, Aachen (DE); Rainald Manfred GIERTH, Aachen (DE); Stefan Peter GRABOWSKI, Neuss (DE)

(73) Assignee: KONINKLIJKE PHILIPS N.V., EINDHOVEN (NL)

(21) Appl. No.: 14/889,623

(22) PCT Filed: May 15, 2014
(86) PCT No.: PCT/EP2014/059914

§ 371 Date: Nov. 6, 2015

(30) Foreign Application Priority Data
May 23, 2013 (EP) 13168850.9

(51) Int. Cl. H01L 51/52; H01L 51/56; H01L 51/00; H01L 51/50

(52) U.S. Cl. CPC H01L 51/5212; H01L 51/5088; H01L 51/56; H01L 51/0017; H01L 51/0037; H01L 2251/303; H01L 2251/558

(57) ABSTRACT

The invention relates to an OLED(1) comprising an etch stop layer (3) between a first electrode (2) and anorganic layer stack (4) and an electrically conductive element (13) arranged in an etched region (6) within a second electrode (5) and the organic layer stack such that the electrically conductive element is electrically connected with the first electrode. The etch stop layer is a hole-injection layer comprising a metal oxide with semi conducting properties. In particular, the OLED may comprise several electrically conductive elements in several etched regions, wherein the electrically conductive elements can be electrically connected with different parts of the first electrode and with each other via an electrical connector (14) for shunting the different parts of the first electrode, which can lead to a more homogenous light emission. The electrical conductive elements may also be used to provide a color tunability. The etch stop layer can reduce the likelihood of the first electrode to be damaged due to etching.

### FIELD OF THE INVENTION

The invention relates to an organic light-emitting device. The invention also relates to a production apparatus and a production method for producing the organic light-emitting device.

### BACKGROUND OF THE INVENTION

An organic light-emitting device (OLED) generally comprises a first electrode, a second electrode and an intermediate organic layer stack. The organic layer stack comprises multiple functional organic thin films, which are adapted to emit light if a voltage difference is applied between the first and second electrodes. At least one electrode is optically transparent and is made of, for instance, indium tin oxide (ITO). This relatively simple electrical configuration cannot easily be adapted to cope with known problems like an often inhomogeneous electrical field between the first and second electrodes, which may result in an inhomogeneous generation of light. The electrical configuration does therefore not easily allow for an improvement of the OLED.

### SUMMARY OF THE INVENTION

It is an object of the present invention to provide an OLED comprising an electrical configuration, which allows for an easier improvement of the quality of the OLED. It is a further object of the present invention to provide a production apparatus and a production method for producing the OLED.

In a first aspect of the present invention an OLED is presented, which comprises:
a first electrode, a second electrode and an intermediate organic layer stack in between the first and second electrodes,
an etch stop layer between the first electrode and the intermediate organic layer stack, wherein the first and second electrodes, the etch stop layer and the intermediate organic layer stack are adapted such that the intermediate organic layer stack emits light, if a voltage is applied to the first and second electrodes, the etch stop layer (3; 103; 203) being a hole-injection layer comprising a metal oxide with semiconducting properties, and
an electrically conductive element arranged in an etched region within the second electrode and the organic layer stack such that the electrically conductive element is electrically connected with the first electrode.

This electrical configuration with the first and second electrodes and the electrically conductive element arranged in the etched region within the second electrode and the organic layer stack such that the electrically conductive element is electrically connected with the first electrode allows for an easier improvement of the quality of the OLED. For instance, the OLED may comprise several of the electrically conductive elements in several of the etched regions, wherein first ends of the electrically conductive elements can be electrically connected with different parts of the first electrode and opposing second ends of the electrically conductive elements can be electrically connected with each other for shunting the different parts of the first electrode. This shunting of different parts of the first electrode through the electrically conductive elements in the etched regions can lead to a relatively homogeneous electrical field between the first and second electrodes, which in turn can lead to a more homogeneous light emission and, thus, to an improved quality of the OLED. The electrical configuration can also be used to improve the quality of the OLED in another way. For instance, the electrical configuration can be used to provide additional functions like a color tunability and thereby improve the quality of the OLED as it will be exemplarily described further below.

Moreover, since between the first electrode and the organic layer stack an etch stop layer is provided, the first electrode is protected by the etch stop layer such that a possible damage of the first electrode during an etching process for generating the etch regions can be reduced, in particular, avoided. This reduction, in particular, avoidance, of a generally possible damage of the first electrode during an etching process can further improve the quality of the OLED.

The first electrode and the etch stop layer are preferentially transparent to the light emitted by the organic layers. Moreover, preferentially the OLED comprises a first side and an opposing second side, wherein the second electrode is located at the second side of the organic light-emitting device, wherein the etched regions extend from the second side through the second electrode and the organic layer stack to the etch stop layer, wherein the second ends of the electrically conductive elements are electrically connected via an electrical connector arranged at the second side.

The first electrode preferentially comprises at least one of the group consisting of ITO, poly(3,4-ethylenedioxythiophene) (PEDOT), a carbon based material and zinc oxide (ZnO). The carbon based material may be nanotubes or graphene. These materials are electrically conductive and transparent to visible light and are therefore very suited as first electrode material.

The etch stop layer acts as barrier for reactive ions or other species emerging in an etch process and therefore protects the first electrode against damage. This layer is chemical stable against reactive ions used to etch a region into an organic layer stack. Typical process gases are, for example, BCl₃, Cl₂, O₂ and N₂.

The etch stop layer is also a hole-injection layer and it comprises a metal oxide with semiconducting properties. In an embodiment, the etch stop layer comprises at least one of the group consisting of aluminum oxide, indium oxide, gallium oxide, tin oxide, and the transition metal oxides. Examples of suitable transition metal oxides are molybdenum oxide, vanadium oxide, nickel oxide, tungsten oxide, silver oxide, zinc oxide, titanium oxide, zirconium oxide, hafnium oxide, and tantalum oxide. It is to be understood that this group also includes (i) mixtures of the aforementioned metal oxides, such as indium gallium zinc oxide (IGZO), and (ii) doped metal oxides such as aluminum-doped zinc oxide, fluorine-doped tin oxide (FTO), indium-doped tin oxide (ITO), and antimony-doped tin oxide (ATO).

The etch stop is preferentially relatively thin; in particular, it has preferentially a thickness in the nanometer range. Its thickness may be, for instance, smaller than 50 nm. This small thickness leads to a very small absorption of the light emitted by the organic layer stack.

Moreover, in an embodiment the etch stop layer may have been deposited via at least one technique of the group consisting of thermal evaporation, sputtering, spin coating, printing, especially ink-jet printing, slot-dye coating, chemical vapor deposition, atomic layer deposition and molecular layer deposition.

In an embodiment, between the etch stop layer and the organic layer stack a further hole-injection layer or hole-transport layer is arranged. This further hole-injection layer or hole-transport layer may comprise α-NPD, which may be p-doped. Using a further hole-injection layer or hole-transport layer can further improve the quality of the OLED.

In a further preferred embodiment the etch stop layer covers a part of the first electrode. By only partially covering the first electrode, the etch stop layer can act as a mask during the etching process, which can allow for an easy provision of etched regions and electrically conductive elements within the etched regions, which extend to different layers of the OLED. The etch stop layer may be directly provided on the first electrode or further layers may be provided between the etch stop layer and the first electrode, i.e. the etch stop layer may directly cover a part of the first electrode or there may be further layers between the etch stop layer and the part of the first electrode.

The OLED may comprise a third electrode and a further organic layer stack arranged between the first and third electrodes. Furthermore, the etch stop layer may partly cover the first electrode, wherein the OLED comprises at least one electrically conductive element of a first kind arranged in at least one etched region of a first kind, which extends from and through the second electrode and through the intermediate organic layer stack to the etch stop layer such that the at least one electrically conductive element of the first kind is electrically connected with the first electrode, and at least one electrically conductive element of a second kind arranged in at least one etched region of a second kind, which extends from and through the second electrode, through the intermediate organic layer stack, through the first electrode and through the further intermediate organic layer stack to the third electrode such that the at least one electrically conductive element of the second kind is electrically connected with the third electrode. Preferentially, also between the further intermediate organic layer stack and the third electrode an etch stop layer is provided. This electrical configuration allows addressing the first, second and third electrodes such that the electrical fields between the first and second electrodes and between the first and third electrodes can be adjusted as desired, in order to provide, for instance, a colour tunability of the OLED.

In a second aspect of the present invention a production apparatus for producing an OLED according to the first aspect is presented, wherein the production apparatus adapted to:
provide the first electrode, the second electrode and the intermediate organic layer stack in between the first and second electrodes,
provide the etch stop layer between the first electrode and the intermediate organic layer stack, wherein the first and second electrodes, the etch stop layer and the intermediate organic layer stack are provided such that the intermediate organic layer stack emits light, if a voltage is applied to the first and second electrodes,
etch a region into the second electrode and the organic layer stack, and
provide the electrically conductive element in the etched region within the second electrode and the organic layer stack such that the electrically conductive element is electrically connected with the first electrode.

In a third aspect of the present invention a production method for producing an OLED according to the first aspect is presented, wherein the production method comprises
providing the first electrode, the second electrode and the intermediate organic layer stack in between the first and second electrodes,
providing the etch stop layer between the first electrode and the intermediate organic layer stack, wherein the first and second electrodes, the etch stop layer and the intermediate organic layer stack are provided such that the intermediate organic layer stack emits light, if a voltage is applied to the first and second electrodes,
etching a region into the second electrode and the organic layer stack,
providing the electrically conductive element in the etched region within the second electrode and the organic layer stack such that the electrically conductive element is electrically connected with the first electrode.

It shall be understood that the OLED according to the first aspect, the production apparatus according to second aspect, and the production method according to the third aspect have similar and/or identical preferred embodiments, in particular, as defined in the dependent claims.

It shall be understood that a preferred embodiment of the invention can also be any combination of the dependent claims or above embodiments with the respective independent claim.

These and other aspects of the invention will be apparent from and elucidated with reference to the embodiments described hereinafter.

### BRIEF DESCRIPTION OF THE DRAWINGS

In the following drawings:

FIGS. 1 to 3 show exemplarily and schematically different embodiments of an OLED,

FIG. 4 shows exemplarily and schematically an embodiment of a production apparatus for producing an OLED, and

FIG. 5 shows a flowchart exemplarily illustrating an embodiment of a production method for producing an OLED.

### DETAILED DESCRIPTION OF EMBODIMENTS

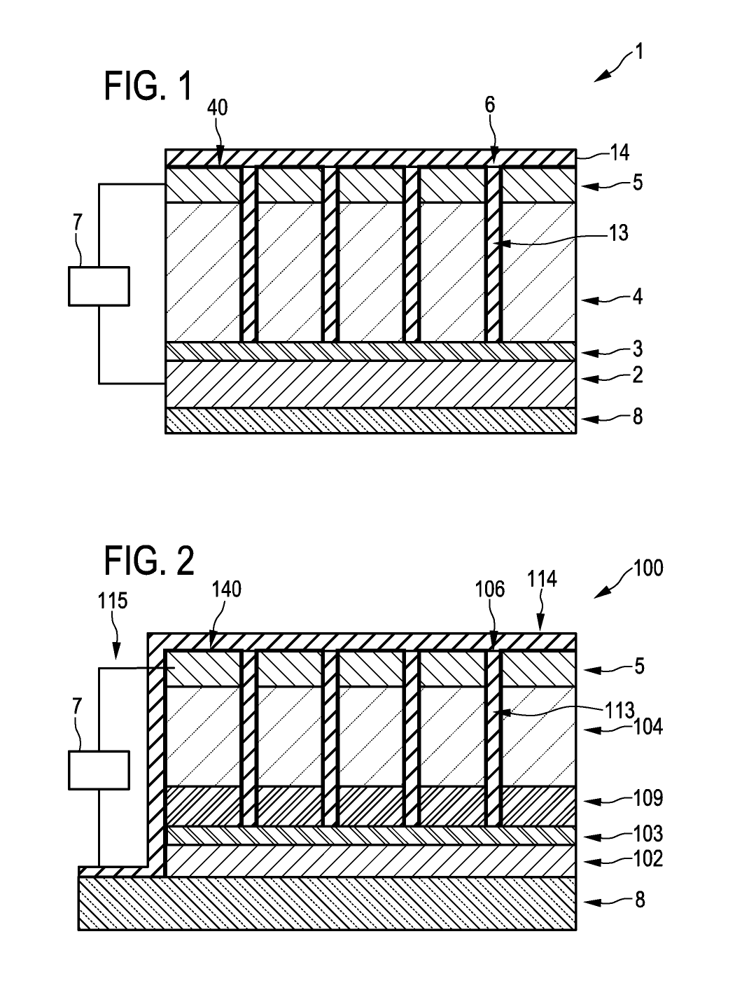

FIG. 1 shows schematically and exemplarily an embodiment of an OLED. The OLED 1 comprises a first electrode 2 on a substrate 8, a second electrode 5 and an intermediate organic layer stack 4 in between the first and second electrodes 2, 5, wherein between the first electrode 2 and the intermediate organic layer stack 4 an etch stop layer 3 is provided. The first and second electrodes 2, 5, the etch stop layer 3 and the intermediate organic layer stack 4 are adapted such that the intermediate organic layer stack 4 emits light, if voltage is applied to the first and second electrodes 2, 5 by using the voltage source 7.

The second electrode 5 and the organic layer stack 4 comprise etched regions being, in this embodiment, etched holes 6, which extend from the second electrode 5 towards the border between the organic layer stack 4 and the etch stop layer 3. The etched holes 6 are substantially perpendicular to the planes defined by the substrate 8, the first electrode 2, the etch stop layer 3 and the second electrode 5. Electrically conductive elements 13 are arranged within the etched holes 6, wherein the electrically conductive elements 13 are electrically connected via an electrical connecting element 14 on a side of the OLED 1 being opposite to the substrate 8 for shunting different parts of the first electrode 2. Electrically insulating material 40 is provided between a) the electrically conductive elements 13 and the electrical connecting element 14 and b) the organic layer stack 4 and the second electrode 5 (not shown in FIG. 1 for clarity reasons).

The insulating material is preferentially a dielectric material, which may be provided by a printing or depositing technique. The insulating material can also be provided by other techniques. For instance, if the second electrode 5 is metallic, it may be oxidized for providing the insulating material between a) the second electrode 5 and b) the electrical connecting element 14 and the electrically conductive elements 13. Also other techniques for providing the insulating material are possible. For example, the etched holes 6 and the top surface of the second electrode 5 can be provided with an insulating material, wherein then this insulating material can be partly removed, in particular, partly etched away, whereupon metal can be filled in the etched holes having insulating inner walls. Finally, the resulting electrically conductive elements 13 can be electrically connected via the electrical connecting element 14.

The first electrode 2 and the etch stop layer 3 are transparent to the light emitted by the organic layer stack 4, whereas in this embodiment the second electrode 5 is not transparent. The OLED 1 is therefore a bottom emitting OLED. In another embodiment also the second electrode 5 may be transparent.

The substrate 8 is preferentially a glass or plastic substrate, and the second electrode 2 is preferentially formed by a layer of an electrically conductive transparent material like ITO, PEDOT, a carbon based material, for instance, graphene, or ZnO.

The etch stop layer 3 acts as a barrier for reactive ions or other species emerging in an etching process and therefore protects the first electrode 2 against damage. The etch stop layer 3 is chemically stable against the reactive ions used to etch the holes 6 into the second electrode 5 and the organic layer stack 4. The etching process may be performed by using process gases like BCl₃, Cl₂, O₂ or N₂ such that the etch stop layer 3 may be chemically stable against reactive ions generated, if these process gases are used. Moreover, the etch stop layer 3 is adapted such that charge carriers can penetrate the etch stop layer 3.

The etch stop layer 3 is not only adapted to act as a barrier for the etching process for protecting the first electrode, but also as a hole-injection layer. For this purpose the etch stop layer 3 comprises a metal oxide with semiconducting properties. Examples of suitable metal oxides are aluminum oxide, indium oxide, gallium oxide, and tin oxide. Further examples of suitable metal oxides are transition metal oxides such as molybdenum oxide, vanadium oxide, nickel oxide, tungsten oxide, silver oxide, zinc oxide, titanium oxide, zirconium oxide, hafnium oxide, and tantalum oxide.

The etch stop layer 3 has preferentially a thickness being smaller than 50 nm, further preferred smaller than 10 nm and even further preferred smaller than 5 nm. If the etch stop layer 3 is made of an electrically insulating material, the thickness is chosen such that charge carriers can tunnel through the etch stop layer 3.

The etch stop layer 3 may have been deposited on the first electrode 2 by using known deposition techniques like thermal evaporation, sputtering, spin coating, chemical vapor deposition, printing, atomic layer deposition or molecular layer deposition. Also the other layers like the first electrode 2, the layers of the organic layer stack 4 and the layer forming the second electrode 5 may be deposited by using known deposition techniques.

The organic layer stack may comprise, for instance, Di-[4-(N,N-ditolyl-amino)-phenyl]cyclohexane (TAPC)/1,1-bis[4-[N,N-di(p-tolyl)amino]phenyl]cyclohexane (TCTA)/tris(2-phenylpyridine)iridium(III) (Ir(ppy)3) doped into 4,4′-N,N′-dicarbazolylbiphenyl (CBP) as the host materials/1,3,5-tri(phenyl-2-benzimidazolyl)-benzene (TPBi). However, the organic layer stack can also comprise other OLED materials. The electrical conductive elements preferentially comprise metals like Ag or Cu. The electrical connecting element preferentially also comprises a metal, in particular, Al, Ag, Au, Cu or Mo. The etched holes may be filled with the electrically conductive material for providing the electrically conductive elements by using, for instance, ink-jet printing, evaporation, sputtering, plasma-enhanced chemical vapor deposition or atomic layer deposition.

FIG. 2 shows schematically and exemplarily a further embodiment of an OLED. Also in this embodiment the OLED 100 comprises a substrate 8, a first electrode 102 forming an anode, an etch stop layer 103, an organic layer stack 104, a second electrode 5 forming a cathode, electrically conductive elements 113 in etched holes 106, an electrically connecting element 114, and a voltage source 7 electrically connecting the first and second electrodes. These components can be made of the same materials and in the same way as the corresponding components described above with reference to FIG. 1. However, in this embodiment the OLED 100 further comprises a further hole-injection layer 109 between the etch stop layer 103 and the organic layer stack 104. The further hole-injection layer 109 may comprise α-NPD, which may be p-doped. Alternatively or in addition, the hole-injection layer 109 may also comprise another hole-injection material like TAPC, TCTA or CBP.

During the etching process for generating the holes 106 the etch stop layer 103 does not cover the entire material forming the first electrode 102 such that in an outer region 115 also the material forming the first electrode 102 is etched away. The inner etched regions 106 being, in this embodiment, etched holes, extend until the etch stop layer 103. These etched holes 106 are filled with the electrically conductive elements 113, which are electrically connected via the electrical connector 114, in order to shunt different parts of the first electrode 102. The electrical connector 114 extends through the outer etched region 115 onto the substrate 8.

In the embodiment shown in FIG. 2 the substrate 8 is preferentially a glass or plastic substrate, the anode layer, i.e. the first electrode 102, is preferentially formed by PEDOT, the etch stop layer 103 is preferentially made of molybdenum oxide, the further hole-injection layer 109 is preferentially made of α-NPD, which may be p-doped, and the organic layer stack 104 preferentially comprises a hole-transport layer, which may be made of CBP, an emission layer preferentially made of CBP doped with Ir(ppy)3 and an electron-transport layer preferentially made of TPBI. The cathode layer, i.e. the second electrode 5, is preferentially made of LiF/Al.

The OLED 100 shown in FIG. 2 further comprises insulating material 140 for insulating the electrically conductive elements 113 from the second electrode 5, the organic layer stack 104 and the hole-injection layer 109 and for electrically insulating the electrical connector 114 from the second electrode 5, the organic layer stack 104, the hole-injection layer 109, the etch stop layer 103 and the first electrode 102.

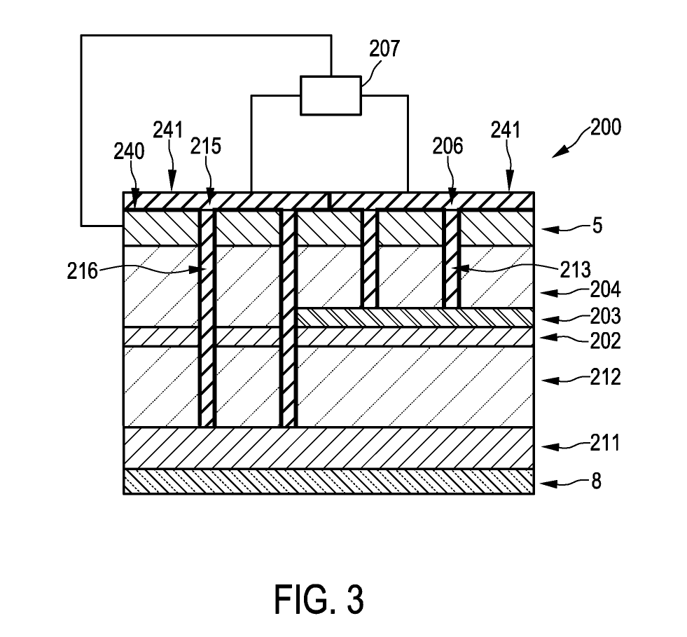

FIG. 3, which is, as FIGS. 1 and 2, not to scale, shows schematically and exemplarily a further embodiment of an OLED. In this embodiment the OLED 200 also comprises a substrate 8, a first electrode 202, an etch stop layer 203, an organic layer stack 204, a second electrode 5, electrically conductive elements 213, 216 and electrical connectors 214, 241 which are made of materials that are similar to the materials used for the corresponding components of the OLEDs 1, 100 described above with reference to FIGS. 1 and 2. However, in this embodiment the OLED 200 further comprises a third electrode 211 and a further organic layer stack 212 sandwiched between the first electrode 202 and the third electrode 211. Moreover, also in this embodiment the etch stop layer 203 only partly covers the first electrode 202, wherein in this embodiment the further organic layer stack 212 is continuous, i.e. does not comprise etched holes, between the first and third electrodes 202, 211 in a region covered by the etch stop layer 203, because the etch stop layer 203 has protected this part of the further organic layer stack 212 from being etched. Thus, the OLED 202 comprises etched holes 206, 215 having different lengths, wherein a first type of etched holes 206 extends from the second electrode 5 through the organic layer stack 204 to the border between the organic layer stack 204 and the etch stop layer 203 and wherein a second type of etched holes 215 extends from the second electrode 5 through the organic layer stack 204, the second electrode 202 and the further organic layer stack 212 to the border between the further organic layer stack 212 and the third electrode 211. The etched holes 206, 215 comprise electrically conductive elements 213, 216, which are electrically connected by using electrical connectors 214, 241, in order to shunt different parts of the first electrode 202 and of the third electrode 211.

Moreover, also in this embodiment, the OLED 200 comprises insulating material 240. The insulating material 240 insulates the first electrical connector 241 from the second electrical connector 214 and from the second electrode 5, the second electrical connector 214 from the second electrode 5, the longer electrically conductive elements 216 from the second electrode 5, the organic layer stack 204, the first electrode 202 and the further organic layer stack 212, and the shorter electrically conductive elements 213 from the second electrode 5 and the organic layer stack 204.

Also between the further organic layer stack 212 and the third electrode 211, an etch stop layer can be provided, which may comprise materials, which are similar to the materials of the etch stop layer 203. Moreover, also the third electrode 211 is preferentially optically transparent and is made of, for instance, ITO, PEDOT or graphene.

The OLED device further comprises a voltage source 207 for providing a voltage to the first electrode 202 via the electrically conductive elements 213 and the second electrical connector 214, for providing a voltage to the third electrode 211 via the electrically conductive elements 216 and the first electrical connector 241 and to provide voltage to the second electrode 5. By adjusting the voltages applied to the three electrodes, the color of the light emitted by the OLED 200 may be tuned. For instance, the organic layer stack 204 can be adapted to provide a first colour, if voltage is applied to the first and second electrodes, and the further organic layer stack 212 can be adapted to provide a second color, if voltage is applied to the first and third electrodes. By adjusting the voltages applied to the electrodes, the amount of the first and second colors can be adjusted.

The first electrode 202 is also transparent and may be made of, for instance, ITO, a thin Ag-layer, a thin Al/Ag alloy layer, et cetera.

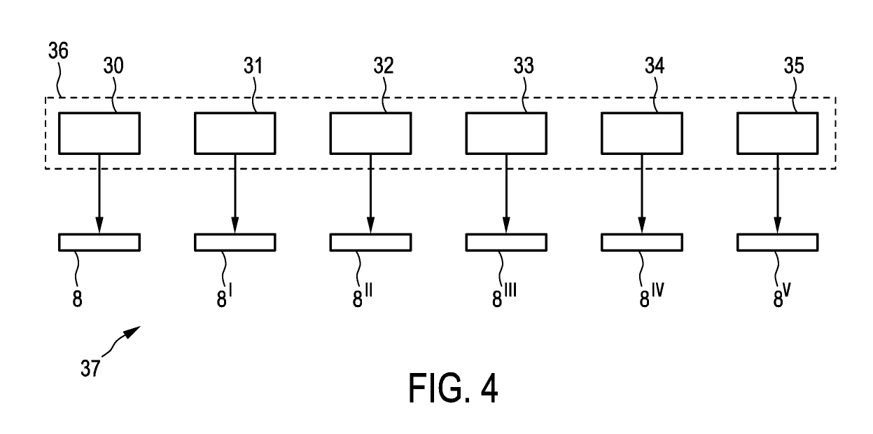

FIG. 4 shows schematically and exemplarily an embodiment of a production apparatus for producing an OLED. The production apparatus 37 comprises an electrode and organic layer stack providing unit 36 for providing a first electrode, a second electrode and an intermediate organic layer stack in between the first and second electrodes, wherein between the first electrode and the intermediate organic layer stack an etch stop layer is provided and wherein the first and second electrodes, the etch stop layer and the intermediate organic layer stack are adapted such that the intermediate organic layer stack emits light, if a voltage is applied to the first and second electrodes. In particular, the electrode and organic layer stack providing unit 36 comprises a first electrode providing unit 30 for depositing an electrically conductive layer on a substrate 8 for forming the first electrode. The electrode and organic layer stack providing unit 36 further comprises an etch stop layer providing unit 31 for depositing the etch stop layer on the first electrode. In FIG. 4 the reference number 8ⁱ denotes the substrate 8 with the first electrode, whereas the substrate 8 with the first electrode and with the etch stop layer is denoted by the reference number 8ⁱⁱ.

The electrode and organic layer stack providing unit 36 further comprises an organic layer stack providing unit 32 for providing the organic layer stack on the etch stop layer. The resulting substrate with the first electrode, the etch stop layer and the organic layer stack is denoted by the reference number 8ⁱⁱⁱ. A second electrode providing unit 33 deposits an electrically conductive material on the organic layer stack forming the second electrode, wherein the result of this deposition is denoted by the reference number 8^{iv}. The electrode and organic layer stack providing unit 36 further comprises an etching unit 34 for etching holes into the second electrode and the organic layer stack, wherein the resulting component is denoted in FIG. 4 by reference number 8^{v}. An electrically conductive elements providing unit 35 provides the electrically conductive elements in the etched holes and electrically connects the electrically conductive elements by using an electrical connector. The electrodes of the resulting OLED can finally be connected to a voltage source for generating light within the organic layer stack.

The production apparatus 37 can be adapted to produce different configurations of OLEDs, which comprise at least first and second electrodes, an intermediate organic layer stack, an etch stop layer between the first electrode and the organic layer stack, and electrically conductive elements, which are electrically connected, in the etched holes. For instance, the production apparatus 37 can also be adapted to produce the configuration shown in FIG. 3, wherein in this case the organic layer stack providing unit 32 may be used twice for also providing the further organic layer stack and one of the first and second electrode providing units 30, 33 may be used to provide the third electrode, or the production apparatus may comprise a further unit for providing the third electrode.

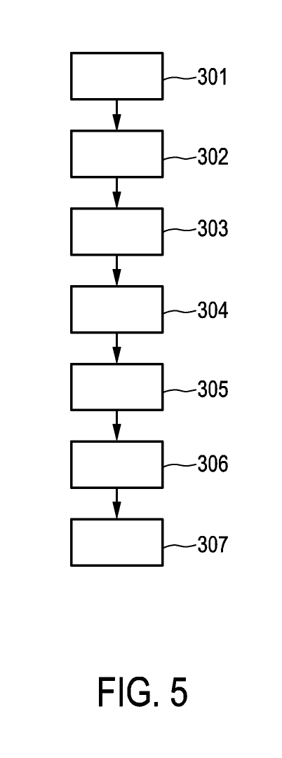

FIG. 5 shows schematically and exemplarily an embodiment of a production method for producing an OLED. The production method is adapted to provide a first electrode, a second electrode and an intermediate organic layer stack in between the first and second electrodes, wherein between the first electrode and the intermediate organic layer stack an etch stop layer is provided and wherein the first and second electrodes, the etch stop layer and the intermediate organic layer stack are adapted such that the intermediate organic layer stack emits light, if a voltage is applied to the first and second electrodes. In particular, in this embodiment in step 301 a substrate is provided with a first electrode layer by depositing electrically conductive material on the substrate. In step 302 an etch stop layer is deposited on the first electrode layer and in step 303 an organic layer stack is deposited on the etch stop layer. A second electrode layer is deposited on the organic layer stack in step 304 and in step 305 holes are etched in the second electrode layer and the organic layer stack. In step 306 the etched holes are filled with electrically conductive material for forming the electrically conductive elements within the etched holes and the electrically conductive elements are electrically connected for shunting different parts of the first electrode layer. In step 307 the electrode layers of the OLED are electrically connected to a voltage source.

The transparent first electrode may have a relatively small conductivity, which may generally lead to a voltage drop across the first electrode, which in turn may affect the efficiency of the OLED and which may cause an inhomogeneous light emission. Contacting the transparent first electrode from the back side of the OLED via etched holes filled with a conductive material as described above with reference to FIGS. 1 to 3 provides the possibility to shunt the first electrode, which in these embodiments is a bottom electrode, but which may also be a top electrode. By tuning the distance of the etched holes a relatively homogeneous light emission can be achieved even on very large areas. In order to protect the transparent electrode against highly reactive precursors, which may be used to etch the holes into the OLED, an etch stop layer is placed on top of the damageable electrode. The etch stop layer is preferentially highly transparent in the visible region and does not interfere with the electro-optical performance of the OLED.

The class of materials that is used for the etch stop layer is that of the metal oxides with semiconducting properties, in particular aluminum oxide, indium oxide, gallium oxide, tin oxide, and the transition metal oxides such as molybdenum oxide, vanadium oxide, nickel oxide, tungsten oxide, silver oxide, zinc oxide, titanium oxide, zirconium oxide, hafnium oxide, and tantalum oxide. If one or several of these materials are used as etch stop layer, the etch stop layer will also have the function of a hole-injection layer. The thickness of the etch stop layer is preferentially in the nanometer range.

In an embodiment the OLED may comprise a PEDOT bottom electrode as first electrode, a molybdenum oxide layer on the first electrode as hole-injection layer and etch stop layer, on top of the molybdenum oxide layer an α-NPD layer as hole transport layer, on top of the α-NPD layer an organic layer stack comprising Alq₃ as emission and electrode transport layer and on top of the organic layer stack a LiF/Al top electrode as second electrode. If in this embodiment the OLED would not comprise the molybdenum oxide layer, the etch process would remove all carbon-based materials, thus α-NPD, Alq₃ and PEDOT. On the other hand, the hole etch process into the OLED structure will abruptly stop at the interface to the molybdenum oxide layer. Thus, the PEDOT electrode is protected and back contacting via the etched holes is feasible.

The etch stop layer can be used to contact an electrode of the OLED, which is embedded between organic layer stacks, in a controlled way as shown in FIG. 3. The etch stop layer might cover the embedded electrode 202 completely or only partially, depending on the application. Such configuration opens up color tunable OLED operation.

Other variations to the disclosed embodiments can be understood and effected by those skilled in the art in practicing the claimed invention, from a study of the drawings, the disclosure, and the appended claims.

In the claims, the word “comprising” does not exclude other elements or steps, and the indefinite article “a” or “an” does not exclude a plurality.

A single unit or device may fulfill the functions of several items recited in the claims. The mere fact that certain measures are recited in mutually different dependent claims does not indicate that a combination of these measures cannot be used to advantage.

Procedures like the provision of the first, second and optionally third electrodes, the etching process, the provision of the etch stop layer, the provision of the organic layer stack, the provision of the electrically conductive elements, the provision of the electrical connector for electrically connecting the electrically conductive elements in the etched holes, et cetera performed by one or several units or devices can be performed by any other number of units or devices. For example, steps 301 to 307 can be performed by a single unit or by any other number of different units. The control of the production apparatus in accordance with the production method can be implemented as program code means of a computer program and/or as dedicated hardware.

A computer program may be stored/distributed on a suitable medium, such as an optical storage medium or a solid-state medium, supplied together with or as part of other hardware, but may also be distributed in other forms, such as via the Internet or other wired or wireless telecommunication systems.

Any reference signs in the claims should not be construed as limiting the scope.

The invention relates to an OLED comprising an etch stop layer between a first electrode and an organic layer stack and an electrically conductive element arranged in an etched region within a second electrode and the organic layer stack such that the electrically conductive element is electrically connected with the first electrode. In particular, the OLED may comprise several electrically conductive elements in several etched regions, wherein the electrically conductive elements can be electrically connected with different parts of the first electrode and with each other via an electrical connector for shunting the different parts of the first electrode, which can lead to a more homogenous light emission. The electrical conductive elements may also be used to provide a color tunability. The etch stop layer can reduce the likelihood of the first electrode to be damaged due to etching.

1. An organic light-emitting device comprising:
a first electrode, a second electrode and an intermediate organic layer stack in between the first and second electrodes,
an etch stop layer between the first electrode and the intermediate organic layer stack, wherein the first and second electrodes, the etch stop layer and the intermediate organic layer stack are adapted such that the intermediate organic layer stack emits light, if a voltage is applied to the first and second electrodes, the etch stop layer being a hole-injection layer comprising a metal oxide with semiconducting properties, and
an electrically conductive element arranged in an etched region within the second electrode and the organic layer stack such that the electrically conductive element is electrically connected with the first electrode.

2. The organic light-emitting device according to claim 1, wherein the metal oxide is chosen from the group consisting of aluminum oxide, indium oxide, gallium oxide, tin oxide, and the transition metal oxides.

3. The organic light-emitting device according to claim 1, wherein the organic light-emitting device comprises several electrically conductive elements in etched regions, wherein first ends of the electrically conductive elements are electrically connected with different parts of the first electrode and opposing second ends of the electrically conductive elements are electrically connected with each other for shunting the different parts of the first electrode.

4. The organic light-emitting device according to claim 1, wherein the etch stop layer has a thickness being smaller than 50 nm.

5. The organic light-emitting device according to claim 1, wherein the etch stop layer has been deposited via at least one technique of the group consisting of thermal evaporation, sputtering, spin coating, slot-dye coating, printing, chemical vapor deposition, atomic layer deposition and molecular layer deposition.

6. The organic light-emitting device according to claim 1, wherein between the etch stop layer and the organic layer stack a further hole-injection layer is arranged.

7. The organic light-emitting device according to claim 1, wherein the etch stop layer covers a part of the first electrode.

8. The organic light-emitting device according to claim 1, wherein the organic light-emitting device comprises a third electrode and a further organic layer stack arranged between first and third electrodes.

9. The organic light-emitting device according to claim 8, wherein the etch stop layer partly covers the first electrode, wherein the organic light-emitting device comprises at least one electrically conductive element of a first kind arranged in at least one etched region of a first kind, which extends from and through the second electrode and through the intermediate organic layer stack) to the etch stop layer such that the at least one electrically conductive element of the first kind is electrically connected with the first electrode, and at least one electrically conductive element of a second kind arranged in at least one etched region of a second kind, which extends from and through the second electrode, through the intermediate organic layer stack, through the first electrode and through the further intermediate organic layer stack to the third electrode such that the at least one electrically conductive element of the second kind is electrically connected with the third electrode.

10. The organic light-emitting device according to claim 1, wherein the first electrode comprises at least one of the group consisting of indium tin oxide, poly(3,4-ethylenedioxythiophene), a carbon based material and zinc oxide.

11. (canceled)

12. A production method for producing the organic light-emitting device according to claim 1, the production method comprising:
providing the first electrode, the second electrode and the intermediate organic layer stack in between the first and second electrodes,
providing the etch stop layer between the first electrode and the intermediate organic layer stack,
etching a region into the second electrode and the organic layer stack,
providing the electrically conductive element in the etched region within the second electrode and the organic layer stack such that the electrically conductive element is electrically connected with the first electrode.
